(19) United States
(12) Patent Application Publication
(10) Pub. No.: US 2012/0326787 A1
(43) Pub. Date: Dec. 27, 2012

(54) VARIABLE-GAIN AMPLIFIER CIRCCUIT AND RECEIVER INCLUDING THE SAME

(75) Inventors: SANG-HOON KANG, NAMDONG-GU (KR); BUM-MAN KIM, POHANG-SI (KR); IN-YOUNG CHOI, SEOUL (KR)

(73) Assignees: POSTECH ACADEMY-INDUSTRY FOUNDATION, POHANG-SI (KR); SAMSUNG ELECTRONICS CO., LTD., SUWON-SI (KR)

(21) Appl. No.: 13/526,730

(22) Filed: Jun. 19, 2012

(30) Foreign Application Priority Data
Jun. 21, 2011 (KR) 10-2011-0060361

(51) Int. Cl. H03G 3/30; H03F 3/45

(52) U.S. Cl. 330/254

(57) ABSTRACT

A variable-gain amplifier (VGA) circuit comprises a plurality of cascaded VGAs each having a gain that varies linearly according to a gain control voltage. The VGA circuit has an overall gain that varies exponentially according to the gain control voltage without the use of an exponential function generator circuit.

### CROSS-REFERENCE TO RELATED APPLICATIONS

This application claims priority under 35 U.S.C. §119 to Korean Patent Application No. 10-2011-0060361 filed on Jun. 21, 2011, the disclosure of which is hereby incorporated by reference in its entirety.

### BACKGROUND OF THE INVENTION

Embodiments of the inventive concept relate generally to electronic circuit technologies. More particularly, embodiments of the inventive concept relate to a variable-gain amplifier (VGA) circuit and a receiver incorporating the VGA circuit.

A VGA circuit amplifies an input signal with a variable amount of gain. Typically, the amount of gain is varied in response to a gain control signal. In some contexts, the gain may be controlled to adjust the magnitude of the input signal for compatibility with an analog-to-digital converter (ADC). For example, in a receiver, an ADC may require an input signal with a certain magnitude. Accordingly, a VGA circuit may be used to adjust the magnitude of the input signal according to the ADC specifications.

### SUMMARY OF THE INVENTION

According to one embodiment of the inventive concept, a VGA circuit comprises a plurality of VGAs arranged in a cascaded configuration and configured to amplify an input signal with a gain that varies linearly on a decibel scale according to a gain control signal.

According to another embodiment of the inventive concept, a receiver comprises an analog signal processor, a VGA circuit, an ADC, a digital signal processor, and a gain control circuit. The analog signal processor is configured to receive an analog input signal from an antenna and to filter the analog input signal. The VGA circuit comprises a plurality of cascaded VGAs each having a gain that varies linearly according to a gain control voltage, wherein the VGA circuit has an overall gain that varies exponentially according to the gain control voltage without the use of an exponential function generator circuit. The ADC is configured to perform analog-to-digital conversion on an output signal of the VGA circuit. The digital signal processor is configured to generate reception data by performing a digital signal process on an output signal of the ADC. The gain control circuit is configured to generate the gain control signal according to the output signal of the ADC.

According to still another embodiment of the inventive concept, a VGA circuit comprises a plurality of cascaded VGAs each having a gain that varies linearly according to a gain control voltage. The VGA circuit has an overall gain that varies exponentially according to the gain control voltage without the use of an exponential function generator circuit.

These and other embodiments of the inventive concept can eliminate a need for an exponential function generator circuit in a VGA circuit, which can potentially improve the cost and performance of the VGA circuit.

### BRIEF DESCRIPTION OF THE DRAWINGS

The drawings illustrate selected embodiments of the inventive concept. In the drawings, like reference numbers indicate like features.

FIG. 1 is a block diagram of a VGA circuit according to an embodiment of the inventive concept.

FIG. 2 shows an example gain curve of a VGA in the VGA circuit of FIG. 1.

FIG. 3 shows an example gain curve of the VGA circuit of FIG. 1.

FIG. 4 shows an example of a decibel gain curve of the VGA circuit of FIG. 1.

FIG. 5 is a circuit diagram of an example VGA in the VGA circuit of FIG. 1.

FIG. 6 is a circuit diagram of another example VGA in the VGA circuit of FIG. 1.

FIG. 7 is a block diagram of an example receiver comprising a VGA circuit according to an embodiment of the inventive concept.

### DETAILED DESCRIPTION

Embodiments of the inventive concept are described below with reference to the accompanying drawings. These embodiments are presented as teaching examples and should not be construed to limit the scope of the inventive concept.

In the description that follows, where a feature is referred to as being “on,” “connected to” or “coupled with” another feature, it can be directly on, connected or coupled with the other feature or intervening features may be present. In contrast, where a feature is referred to as being “directly on,” “directly connected to” or “directly coupled with” another feature, there are no intervening features present. As used herein, the term “and/or” indicates any and all combinations of one or more of the associated listed items.

Although the terms first, second, third, etc., may be used herein to describe various features, these features should not be limited by these terms. Rather, these terms are used merely to distinguish between different features. Thus, a first feature discussed below could be termed a second feature without changing the meaning of the relevant teachings.

The terminology used herein is for the purpose of describing particular embodiments only and is not intended to be limiting of the inventive concept. As used herein, the singular forms “a,” “an” and “the” are intended to encompass the plural forms as well, unless the context clearly indicates otherwise. The terms “comprises” and/or “comprising,” where used in this specification, indicate the presence of stated features but do not preclude the presence or addition of other features.

Unless otherwise defined, all terms (including technical and scientific terms) used herein have the same meaning as commonly understood by one of ordinary skill in the art. Terms in common usage should be interpreted within the context of the relevant art and not in an idealized or overly formal sense, unless expressly so defined herein.

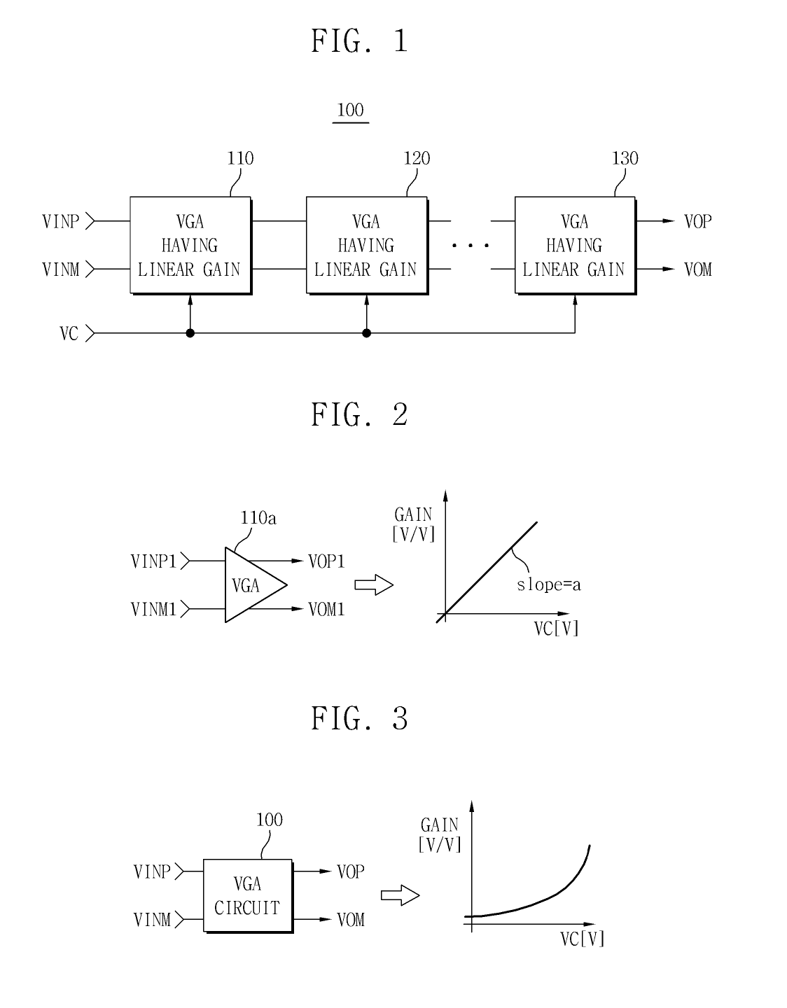

FIG. 1 is a block diagram of a VGA circuit 100 according to an embodiment of the inventive concept.

Referring to FIG. 1, VGA circuit 100 comprises VGAs 110, 120 and 130 connected in a cascaded configuration. VGAs 110, 120, and 130 are configured to change an overall gain of VGA circuit 100 in response to a gain control signal VC. These VGAs change the overall gain such that its magnitude on a decibel scale varies linearly according to gain control signal VC. For example, the overall gain can be changed such that its magnitude in decibels varies in direct proportion to the magnitude of gain control signal VC. Because the decibel scale is a logarithmic function of voltage variation, this means that the overall gain of VGA circuit 100 on a voltage scale (rather than a decibel scale) varies exponentially according to gain control signal VC.

During typical operation, VGA circuit 100 receives and amplifies a pair of input signals VINP and VINM to generate a pair of output signals VOP and VOM.

FIG. 2 shows an example of a gain curve of a VGA in VGA circuit 100 of FIG. 1. Although this example is labeled VGA 110a, the described principles could be applied to the other VGAs in VGA circuit 100.

Referring to FIG. 2, VGA 110a amplifies a pair of input signals VINP1 and VINM1 to generate a pair of output signals VOP1 and VOM1. The gain of VGA 110a has a slope of “a”, and it varies in direct proportion to the magnitude of gain control signal VC.

FIG. 3 shows an example of a gain curve of VGA circuit 100 of FIG. 1.

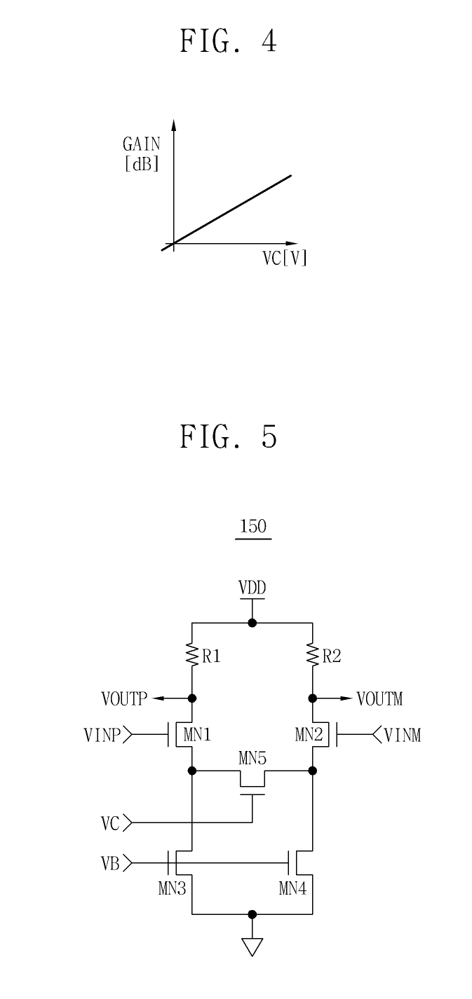

Referring to FIG. 3, VGA circuit 100 amplifies input signals VINP and VINM to generate output signals VOP and VOM. The gain of VGA circuit 100 varies exponentially with the magnitude of gain control signal VC. However, when measured in decibels, the exponential variation shown in FIG. 3 is linear, as illustrated in FIG. 4.

FIG. 4 shows an example of a decibel gain curve showing the gain of VGA circuit 100 of FIG. 1 in units of decibels.

Referring to FIG. 4, the decibel gain of VGA circuit 100 varies in direct proportion to the magnitude of gain control signal VC. In certain embodiments, as described below, this type of decibel gain can be achieved without the use of an exponential function generator circuit. The omission of an exponential function generator can produce a VGA circuit with improved performance and cost specifications.

As illustrated in FIG. 2, each of the VGAs in VGA circuit 100 has linear gain characteristics. Where the linear gain curve has a slope of “a” and a y-intercept of “b”, a voltage gain Av of each VGA may be expressed as the following Equation (1).

Av=a×VC+b=b(1+(a/b)×VC) (1)

Conventionally, to obtain linear gain in decibels, gain control signal VC is changed into the form of e^{VC} by an exponential function generator circuit and applied to each VGA. A voltage gain Av of each conventional VGA may be expressed as shown in the following Equation (2).

Av=b(1+(a/b)×e^{VC}) (2)

By taking the logarithm of Equation (2), linear gain in decibels is obtained as shown in the following Equation (3).

Av(dB)=ln(a/b)+VC (3)

VGA circuit 100 generates exponentially-varying gain, i.e., a gain that varies linearly on a decibel scale, by cascading VGAs having linear gain characteristics without an exponential function generator circuit.

An exponential function e^{x} may be approximated as shown in the following Equation (4).

$${e}^{x} = {lim}_{n \to ∞} {( 1 + \frac{x}{n} )}^{n} \approx {( 1 + \frac{a}{b} x )}^{n} \qquad ( 4 )$$

Extending Equation (1), the overall gain of a VGA circuit having “n” cascaded VGAs can be expressed as Equation (5).

AV(total)=b(1+(a/b)×VC)×b(1+(a/b)×VC)× . . . ×b(1+(a/b)×VC) (5)

The following Equation (6) can be obtained by simplifying Equation (5).

Av(total)=bⁿ(1+(a/b)×VC)ⁿ (6)

The following Equation (7) illustrates a comparison between Equation (4) and Equation (6),

bⁿ×e^{VC}=bⁿ(1+(a/b)×(VC)ⁿ (7)

The following Equation (8) is obtained by taking the logarithm of Equation (7).

Av(total)(dB)=n×ln(b)+VC (8)

Thus, where a plurality of VGAs having linear gain characteristics are cascaded, the overall gain of the VGA circuit is approximately exponential, i.e., linear in decibels. The more VGAs having linear gain characteristics are connected, the closer the overall gain of the VGA circuit may approximate an exponential function.

FIG. 5 is a circuit diagram of an example of a VGA in VGA circuit 100 of FIG. 1.

Referring to FIG. 5, a VGA 150 comprises a first resistor R1, a second resistor R2, a first n-channel metal oxide semiconductor (NMOS) transistor MN1, a second NMOS transistor MN2, a third NMOS transistor MN3, a fourth NMOS transistor MN4, and a fifth NMOS transistor MN5.

First resistor R1 has a first terminal connected with a power supply voltage VDD, and second resistor R2 has a first terminal connected with power supply voltage VDD. First MOS transistor MN1 has a drain connected with a second terminal of first resistor R1 and a gate to which a first input signal VINP is applied. Second MOS transistor MN2 has a drain connected with a second terminal of second resistor R2 and a gate to which a second input signal VINM is applied. Third NMOS transistor MN3 has a drain connected with a source of first NMOS transistor MN1, a gate to which a bias voltage VB is applied, and a source connected to ground. Fourth NMOS transistor MN4 has a drain connected with a source of second NMOS transistor MN2, a gate to which bias voltage VB is applied, and a source connected to ground. Fifth NMOS transistor MN5 is connected between the source of first NMOS transistor MN1 and the source of second NMOS transistor MN2 and operates in response to gain control signal VC.

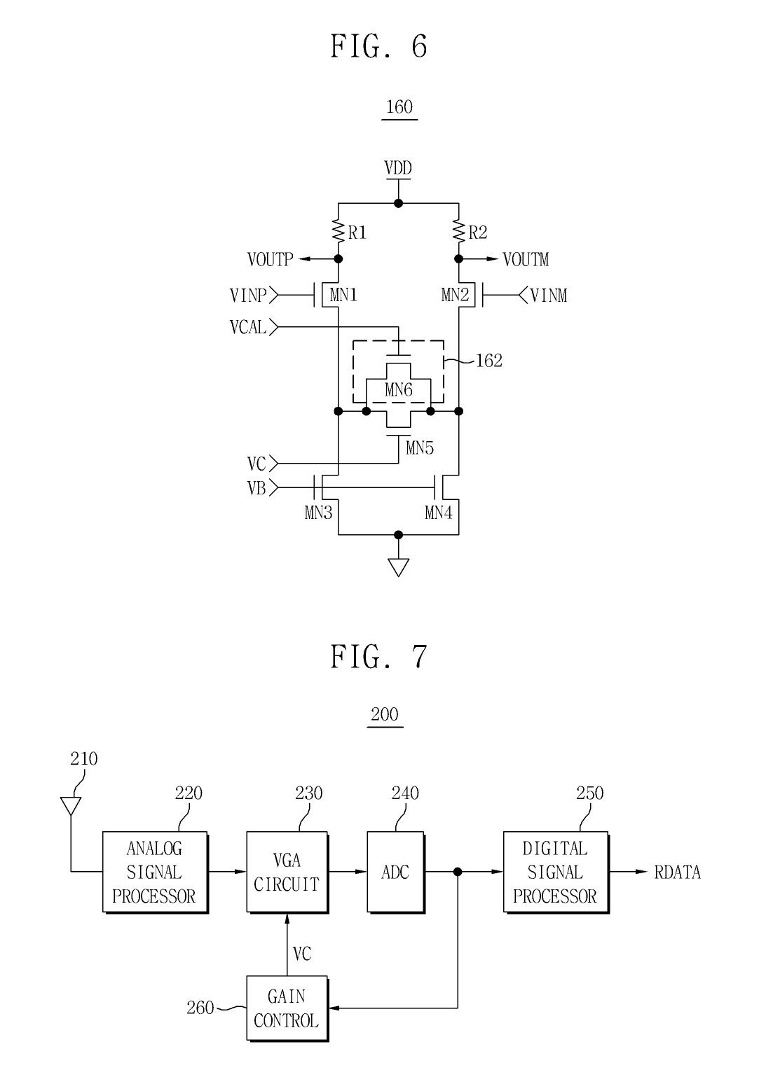

FIG. 6 is a circuit diagram of another example VGA in VGA circuit 100 of FIG. 1.

Referring to FIG. 6, a VGA 160 comprises a first resistor R1, a second resistor R2, a first NMOS transistor MN1, a second NMOS transistor MN2, a third NMOS transistor MN3, a fourth NMOS transistor MN4, a fifth NMOS transistor MN5, and a gain compensation circuit 162. Gain compensation circuit 162 comprises a sixth NMOS transistor MN6.

First resistor R1 has a first terminal connected with a power supply voltage VDD, and second resistor R2 has a first terminal connected with power supply voltage VDD. First MOS transistor MN1 has a drain connected with a second terminal of first resistor R1 and a gate to which a first input signal VINP is applied. Second MOS transistor MN2 has a drain connected with a second terminal of second resistor R2 and a gate to which a second input signal VINM is applied. Third NMOS transistor MN3 has a drain connected with a source of first NMOS transistor MN1, a gate to which a bias voltage VB is applied, and a source connected to ground. Fourth NMOS transistor MN4 has a drain connected with a source of second NMOS transistor MN2, a gate to which bias voltage VB is applied, and a source connected to ground. Fifth NMOS transistor MN5 is connected between the source of first NMOS transistor MN1 and the source of second NMOS transistor MN2 and operates in response to gain control signal VC. Sixth NMOS transistor MN6 is connected in parallel with fifth NMOS transistor MN5 and operates in response to a compensation signal VCAL.

In FIG. 6, one NMOS transistor is connected in parallel with fifth NMOS transistor MN5 to compensate the gain of VGA 160, but VGA 160 could any number of NMOS transistors connected in parallel with fifth transistor MN5 to compensate the gain.

VGA 160 may adjust the gain slope according to the magnitude of gain control signal VC. As an example, assume gain control signal VC and compensation signal VCAL have the same magnitude, a threshold voltage of control transistor MN5 is VTH1, a threshold voltage of compensation transistor MN6 is VTH2, and gain control signal VC has a value smaller than VTH1. Under these conditions, control transistor MN5 and compensation transistor MN6 both may be in an off-state, and each of VGAs 110, 120 and 130 of FIG. 1 may have a small gain.

As another example, assume gain control signal VC and compensation signal VCAL have the same magnitude, the threshold voltage of control transistor MN5 is VTH1, the threshold voltage of compensation transistor MN6 is VTH2, the gain control signal is VC, and VC has a value greater than VTH1 and less than VTH2. Under these conditions, control transistor MN5 is in the on-state, compensation transistor MN6 is in the off state, and a gain slope of each of VGAs 110, 120 and 130 of FIG. 1 may be determined according to a size (e.g., width/length (W/L)) of control transistor MN5.

As yet another example, assume gain control signal VC and compensation signal VCAL have the same magnitude, the threshold voltage of control transistor MN5 is VTH1, the threshold voltage of compensation transistor MN6 is VTH2, the gain control signal is VC, and VC has a greater value than VTH1, control transistor MN5 and compensation transistor MN6 both may be in the on-state, and a gain slope of each of VGAs 110, 120 and 130 of FIG. 1 may be determined by a transconductance (gm) between control transistor MN5 and compensation transistor MN6.

FIG. 7 is a block diagram of an example receiver comprising a VGA circuit according to an embodiment of the inventive concept.

Referring to FIG. 7, a receiver 200 comprises an analog signal processor 220, a VGA circuit 230, an ADC 240, a digital signal processor 250, and a gain control circuit 260.

Analog signal processor 220 receives an analog input signal from an antenna 210 and filters the analog input signal. VGA circuit 230 comprises a plurality of cascaded VGAs having linear gain characteristics without an exponential function generator circuit. VGA circuit 230 has a linear gain in decibels, and it amplifies the output signal of analog signal processor 220 in response to a gain control signal VC. ADC 240 performs analog-to-digital conversion on the output signal of VGA circuit 230, and digital signal processor 250 performs a digital signal process on the output signal of ADC 240 to generate reception data RDATA. Gain control circuit 260 generates gain control signal VC according to the output signal of ADC 240. In other words, it may increase or decrease gain control signal VC in response to changes in the output signal of ADC 240.

As indicated by the foregoing, in some embodiments of the inventive concept, a VGA circuit generates linear gain in decibels using a plurality of cascading VGAs that each linearly change a gain in response to a gain control signal. Thus, the VGA circuit can generate exponentially-varying gain without an exponential function generator circuit. Consequently, a VGA circuit can generate a gain that varies linearly on a decibel scale. Also, a VGA according to certain embodiments of the inventive concept may have at least one compensation transistor connected in parallel with a control transistor operating in response to a gain control signal, which can reduce gain errors in broadband applications.

Embodiments of the inventive concept find application in various contexts, such as such as VGA circuits and receivers comprising a VGA circuit, for example.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

What is claimed is:

1. A variable-gain amplifier (VGA) circuit, comprising a plurality of VGAs arranged in a cascaded configuration and configured to amplify an input signal with a gain that varies linearly on a decibel scale according to a gain control signal.

2. The VGA circuit of claim 1, wherein each of the VGAs has a gain that varies in direct proportion to a magnitude of the gain control signal.

3. The VGA circuit of claim 1, wherein the VGAs have a collective gain that varies exponentially as a function of a magnitude of the gain control signal.

4. The VGA circuit of claim 1, wherein the gain varies on the decibel scale in direct proportion to a magnitude of the gain control signal.

5. The VGA circuit of claim 1, wherein each of the VGAs comprises a compensation transistor connected in parallel with a control transistor, wherein the control transistor operates in response to the gain control signal and is configured to operate in response to a compensation signal.

6. The VGA circuit of claim 5, wherein each of the VGAs has a gain that varies linearly according to a magnitude of the gain control signal.

7. The VGA circuit of claim 5, wherein where the gain control signal and the compensation signal have the same magnitude and the gain control signal has a value smaller than a threshold voltage of the control transistor, the control transistor and the compensation transistor both have an off-state, and each of the VGAs has a small gain.

8. The VGA circuit of claim 5, wherein, where the gain control signal has a value greater than a threshold voltage of the control transistor and less than a threshold voltage of the compensation transistor and the compensation signal has the same magnitude as the gain control signal, the control transistor is in an on-state, the compensation transistor is in an off-state, and a gain slope of each of the VGAs is determined according to a size of the control transistor.

9. The VGA circuit of claim 5, wherein, where the gain control signal and the compensation signal have the same magnitude and the gain control signal has a value greater than a threshold voltage of the compensation transistor, the control transistor and the compensation transistor are both in an on-state, and a gain slope of each of the VGAs is determined by a transconductance between the control transistor and the compensation transistor.

10. The VGA circuit of claim 1, wherein each of the VGAs comprises a plurality of compensation transistors that are connected in parallel with a control transistor operating in response to the gain control signal, wherein the compensation transistors are configured to operate in response to a compensation signal.

11. The VGA circuit of claim 10, wherein the compensation transistors of each VGA have different threshold voltages.

12. The VGA circuit of claim 1, wherein each of the VGAs comprises:
a first resistor having a first terminal connected with a power supply voltage;
a second resistor having a first terminal connected with the power supply voltage;
a first metal oxide semiconductor (MOS) transistor having a drain connected with a second terminal of the first resistor and a gate to which a first input signal is applied;
a second MOS transistor having a drain connected with a second terminal of the second resistor and a gate to which a second input signal is applied;
a third MOS transistor having a drain connected with a source of the first MOS transistor, a gate to which a bias voltage is applied, and a source connected to ground;
a fourth MOS transistor having a drain connected with a source of the second MOS transistor, a gate to which the bias voltage is applied, and a source connected to ground; and
a fifth MOS transistor connected between the source of the first MOS transistor and the source of the second MOS transistor and configured to operate in response to the gain control signal.

13. The VGA circuit of claim 12, wherein each of the VGAs further comprises at least one compensation transistor connected in parallel with the fifth MOS transistor and configured to operate in response to a compensation signal.

14. A receiver, comprising:
an analog signal processor configured to receive an analog input signal from an antenna and to filter the analog input signal;
a variable-gain amplifier (VGA) circuit comprising a plurality of cascaded VGAs each having a gain that varies linearly according to a gain control voltage, wherein the VGA circuit has an overall gain that varies exponentially according to the gain control voltage without the use of an exponential function generator circuit;
an analog-to-digital converter (ADC) configured to perform analog-to-digital conversion on an output signal of the VGA circuit;
a digital signal processor configured to generate reception data by performing a digital signal process on an output signal of the ADC; and
a gain control circuit configured to generate the gain control signal according to the output signal of the ADC.

15. The receiver of claim 14, wherein the overall gain of the VGA circuit varies linearly on a decibel scale according to the gain control voltage.

16. The receiver of claim 14, wherein each of the VGAs comprises a plurality of compensation transistors connected in parallel with a control transistor operating in response to the gain control signal, wherein each of the compensation transistors operates in response to a compensation signal.

17. A variable-gain amplifier (VGA) circuit comprising a plurality of cascaded VGAs each having a gain that varies linearly according to a gain control voltage,
wherein the VGA circuit has an overall gain that varies exponentially according to the gain control voltage without the use of an exponential function generator circuit.

18. The VGA circuit of claim 17, wherein the overall gain of the VGA circuit varies linearly on a decibel scale as a function of a magnitude of the gain control voltage.

19. The VGA circuit of claim 17, wherein each of the VGAs comprises:
a first resistor having a first terminal connected with a power supply voltage;
a second resistor having a first terminal connected with the power supply voltage;
a first metal oxide semiconductor (MOS) transistor having a drain connected with a second terminal of the first resistor and a gate to which a first input signal is applied;
a second MOS transistor having a drain connected with a second terminal of the second resistor and a gate to which a second input signal is applied;
a third MOS transistor having a drain connected with a source of the first MOS transistor, a gate to which a bias voltage is applied, and a source connected to ground;
a fourth MOS transistor having a drain connected with a source of the second MOS transistor, a gate to which the bias voltage is applied, and a source connected to ground; and
a fifth MOS transistor connected between the source of the first MOS transistor and the source of the second MOS transistor and configured to operate in response to the gain control signal.

20. The VGA circuit of claim 19, wherein each of the VGAs further comprises at least one compensation transistor connected in parallel with the fifth MOS transistor and configured to operate in response to a compensation signal.
